(19) United States
(12) Patent Application Publication
(10) Pub. No.: US 2024/0392431 A1
(43) Pub. Date: Nov. 28, 2024

(54) METHOD FOR FORMATION OF DIFFICULT-TO-MACHINE MATERIALS AND MATERIALS RESULTING THEREFROM

(71) Applicant: Orca Sciences LLC, Kirkland, WA (US)

(72) Inventors: Patrick Gallagher, Kirkland, WA (US); Ian McKay, Kirkland, WA (US); Menyoung Lee, Kirkland, WA (US)

(73) Assignee: Orca Sciences LLC, Kirkland, WA (US)

(21) Appl. No.: 18/674,463

(22) Filed: May 24, 2024

Related U.S. Application Data
(60) Provisional application No. 63/468,945, filed on May 25, 2023.
(60) Provisional application No. 63/608,626, filed on Dec. 11, 2023.

(51) Int. Cl. C23C 16/04; C23C 16/56

(52) U.S. Cl. CPC C23C 16/04; C23C 16/56

(57) ABSTRACT

A composite can include: a skeleton comprising skeleton material arranged at predetermined locations; and deposited material deposited on and around the skeleton wherein the deposited material forms a unified material. A method for making a fabricated material can include: receiving a skeleton, depositing material on the skeleton, and optionally processing the fabricated material.

### CROSS-REFERENCE TO RELATED APPLICATIONS

This application claims the benefit of U.S. Provisional Application No. 63/468,945 filed May 25, 2023, and U.S. Provisional Application No. 63/608,626 filed Dec. 11, 2023, each of which is incorporated in its entirety by this reference.

### TECHNICAL FIELD

This invention relates generally to the additive manufacturing field, and more specifically to a new and useful method and material in the additive manufacturing field.

### BRIEF DESCRIPTION OF THE FIGURES

FIGS. 1A and 1B are schematic representations of a top view of an exemplary composite and a cross-sectional view of a composite material through the cross-section indicated in FIG. 1A (note that the skeleton may not always be visible from the top view as it may be covered with the deposited material).

FIGS. 2A and 2B are schematic representations of examples of deposition chambers for forming a skeleton material.

FIGS. 3A and 3B are schematic representations of variants of deposition chambers for forming skeletons (particularly with complex 3D architectures).

FIGS. 4A and 4B are schematic representations of examples of skeleton arrays.

FIG. 5 is a schematic representation of an example of a skeleton array with non-uniform distribution of individual elements.

FIG. 6 is a schematic representation of an example of forming a complex skeleton array (e.g., by combining two or more skeleton arrays).

FIG. 7 is a schematic representation of an example of performing a method by growing a material on a skeleton and reacting the grown material.

FIG. 8 is a schematic representation of an example of performing a method to form a difficult to machine material where the resulting material can incorporate substrate material and/or can be used for cast processing (e.g., forming a metal backed composite).

FIG. 9 is a schematic representation of an example of forming a shaped object by tailoring a design of the skeleton.

FIG. 10 is a schematic representation of an example of a composite material including a plurality of deposited materials on a skeleton. In this specific example, the first deposited material can, for instance, form a conductive (e.g., thermally conductive, ionically conductive, electrically conductive, etc.) pathway within the composite (e.g., when the second deposited material is not or has lower conductivity).

FIG. 11 is a schematic representation of an example of the method.

FIG. 12 is a schematic representation of a top-down view of a void space remaining after depositing deposited material.

### DETAILED DESCRIPTION

The following description of the embodiments of the invention is not intended to limit the invention to these embodiments, but rather to enable any person skilled in the art to make and use this invention.

### 1. Overview

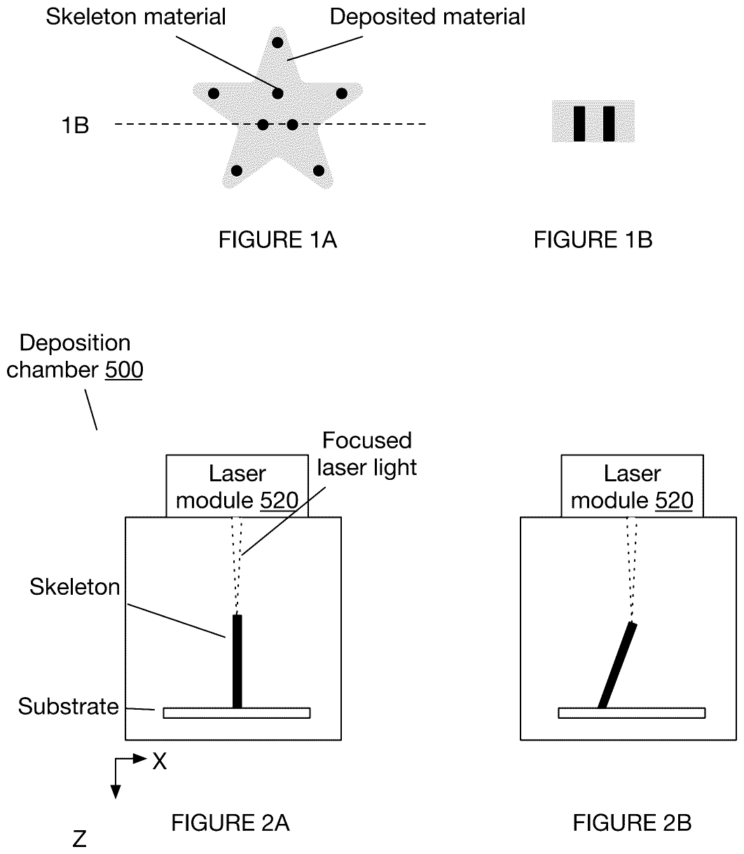

As shown in FIG. 1, a fabricated material can include skeleton material and one or more deposited materials. In variants, the fabricated material can be a composite material, an alloy, a compound, and/or can have any suitable chemical nature. Specific examples of fabricated materials include (but are not limited to): carbon-carbon composites (e.g., graphite-carbon, diamond-carbon, etc.), carbon-silicon composites, titanium-carbon composites, tungsten-carbon composites, tantalum-carbon composites, molybdenum-carbon composites, niobium-carbon composites, zirconium-carbon composites, hafnium-carbon composites, boron-carbon composites, boride-carbon composites, nitride-carbon composites, silicon carbide, titanium carbide, tungsten carbide, tantalum carbide, molybdenum carbide, niobium carbide, zirconium carbide, hafnium carbide, and/or other suitable materials can be realized.

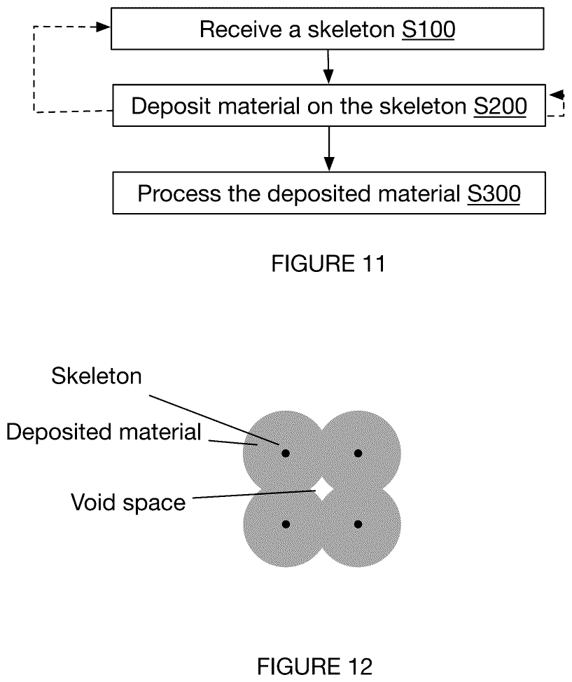

As shown in FIG. 11, a method for making a fabricated material can include: receiving a skeleton S100, depositing material on the skeleton S200, and optionally processing the fabricated material S300. The method preferably functions to produce the fabricated material (e.g., the material of FIG. 1).

The fabricated material (or portions thereof) are typically materials that are expensive and/or challenging to process using traditional machining approaches (e.g., subtractive machining, cutting, grinding, etc.). For instance, the fabricated material (and/or portions thereof) can have a high hardness (e.g., Mohs hardness greater than 7, 8, 9, 10, etc. such as a sclerometer), high (or nonexistent) melting temperature (e.g., exceeding about 1600° C.), high brittleness (e.g., as measured by fracture toughness, Charpy impact strength, uniaxial tensile test, ductility, etc.), and/or can have other properties that result in difficulties machining or processing the material(s). The fabricated material and method to produce thereof can produce a near-net shape such that little processing (e.g., machining) is necessary to achieve a final target shape. For instance, the fabricated material can include through-holes so that through-holes need not be subtractively machined into the material (e.g., by leaving a gap in a skeleton array such that deposited material does not grow into the through hole). Other target shapes and/or features can similarly be designed (e.g., by controlling the skeleton array, deposition of deposited material, etc.).

Applications of the technology (e.g., the fabricated material) include (but are not limited to): rock-cutting tools (e.g., for mining, oil & gas, etc.), geothermal drilling, cutting and/or drilling applications (e.g., for machining hard materials), ballistic armor, heat sinks (e.g., for electronics, for heavy industry, heat pipe, for aerospace applications, etc.), cookware or kitchenware (e.g., non-scratch, non-stick, etc. coatings), aerospace engineering, electrodes (e.g., doped diamond electrodes), carbon-carbon composites (e.g., with high strength-to-weight ratio, stability at high temperatures such as up to about 3000° C., low coefficient of thermal expansion, high thermal conductivity, high electrical conductivities, etc.), battery electrodes (e.g., graphite anodes for lithium-ion batteries), catalysts (e.g., mechanical support for catalysts), chemical reaction vessels (e.g., for high temperature chemical reactions), electrostatic discharge machining, refractory materials, refractory metals, crucible in metal evaporators, heat exchangers in high temperature chemical processes, titanium casting, prosthetics, ceramic composites, artificial stone, brick, radiant heaters, friction surfaces (e.g., performance brake pads, clutch discs, etc.), industrial ceramics, insulation, multi-function parts (e.g., heating and electrical sensing), dental implants, sustainable manufacturing, and/or other suitable applications.

### 2. Technical Advantages

Variants of the technology can confer one or more advantages over conventional technologies.

First, the inventors have discovered a method for fabricating materials that are traditionally challenging to manufacture (e.g., refractory materials; ceramics; refractory metals; cermet; MAX phases such as ‘211’ MAX phase, 312 MAX phase, 413 MAX phase, 514 MAX phase, etc.; composites thereof; etc.) with near arbitrary shape. By using a skeleton, the otherwise difficult to manufacture materials can be formed with a shape derived from the skeleton array (e.g., arrangement of the skeleton, spacing between skeleton pieces, size of the skeleton, height of individual pieces of the skeleton, etc.). Moreover, the skeleton (and/or materials grown, deposited, etc. thereon) can impart improved properties to the fabricated material (e.g., as compared to a fabricated material with otherwise identical appearance but no contained skeleton). Examples of such properties include (but are not limited to): thermal conductivity (and/or insulation), electrical conductivity (and/or insulation), ionic conductivity, ionic and/or molecular resistance (and/or insulation), mechanical robustness (e.g., stiffness, yield strength, ultimate strength, Young's modulus, Poisson ratio, etc. including to resist or to deform under traverse, axial, torsional, etc. loadings in one or more planes or directions), and/or other suitable properties.

Second, the inventors have discovered that process of defining a (near-) net shape can be decoupled from the process of densification. This decoupling, for example, can enable a combination of strengths from defining a near-net shape part (e.g., via a laser-controlled manufacturing process-such as the spatiotemporal control of energy) while using a low-cost, high-throughput densification process (e.g., chemical process, vapor deposition, reaction bonding, etc.) to add most of the mass. Parts produced this way can be cost-competitive even when the laser-controlled material is expensive on a per-mass basis.

Third, variants of the technology can enable low-cost, high throughput manufacturing of difficult to machine or otherwise handle materials (e.g., refractories, ceramics, refractory metals and their alloys, etc.).

Fourth, variants of the technology can be tailored to optimize for growth of the fabricated material. For example (as shown for instance in FIG. 5), the skeleton can have different separations between adjacent portions (for instance where this tailored porosity can be designed to facilitate improved deposition of the fabricated material within the deposition process).

However, further advantages can be provided by the system and method disclosed herein.

### 4. Material

As shown in FIG. 1, a fabricated material can include skeleton material and one or more deposited materials. In variants, the fabricated material can be a composite material (e.g., a composite of the skeleton material and the deposited materials, a composite between two or more deposited materials, etc.), an alloy (e.g., an alloy between the skeleton materials and the deposited materials, an alloy between two or more deposited materials, etc.), a compound, and/or can have any suitable chemical nature.

The fabricated material is preferably between 0.1 and 5%, by volume, skeleton material, where the remainder of the fabricated material is deposited material. As an illustrative example, the fabricated material can be about 1% skeleton material and about 99% deposited material by volume.

The skeleton functions as a site for growth of deposited material. In variants, the skeleton can also be referred to as a scaffold, former, gauge, template, and/or space frame (where the respective terms can also be modified to refer to material thereof). Typically, the skeleton remains in the final fabricated material. However, in some variants, the skeleton material could be removed from the fabricated material (e.g., via etching, diffusion to a surface and machining of the surface, etc.).

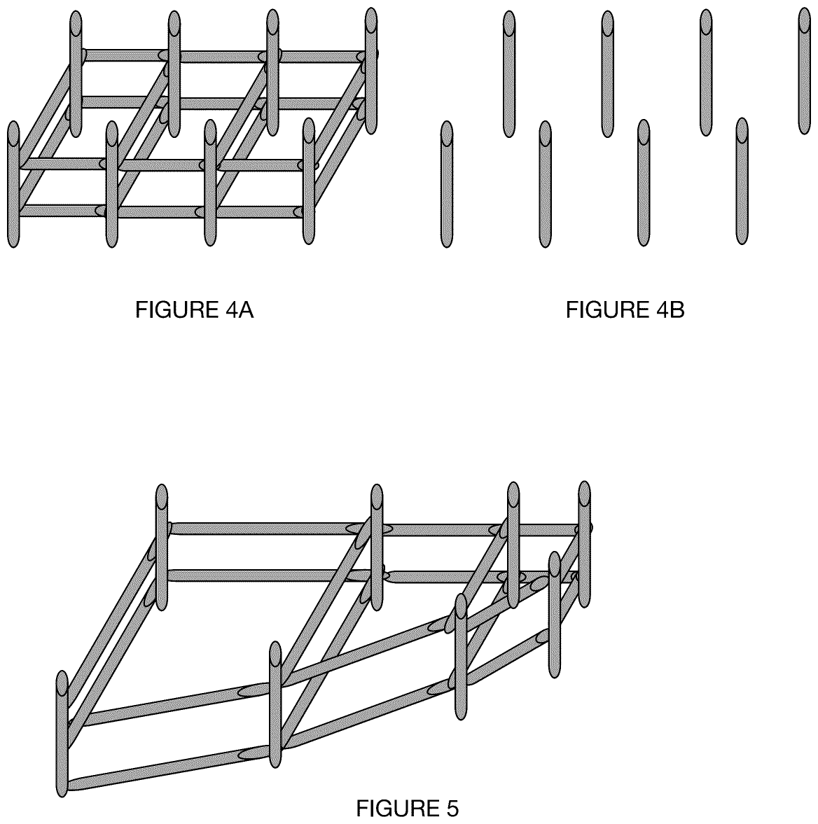

The skeleton material is preferably an array of skeleton structures, where growth of the deposited material can occur on each of the skeleton structures until the deposited materials grown on adjacent skeleton structures merges together. The skeleton structures can be individual (e.g., free-standing, as shown for example in FIG. 4B, etc.) structures and/or can be adjoined together (e.g., as shown for example in FIG. 4A).

In variants where the array of skeleton structures are individual structures, the array of skeleton structures can be arranged on a grid (e.g., a two-dimensional grid of skeleton structures, a one-dimensional grid, etc.), irregularly placed, and/or can otherwise be arranged. Examples of grids include: rectangular grids, hexagonal grids, oblique grid, square grid, triangular grids, circular grids, and/or other suitable grids where a skeleton structure can be placed on corners, edges, and/or other suitable portions of the grid shape(s). The skeleton structures can be equidistant from each nearest neighbor skeleton structure (also referred to as uniform porosity as the void spacing between or within the skeleton is substantially uniform as shown for example in FIG. 4A or FIG. 4B) and/or can be nonequidistant (also referred to as nonuniform porosity and/or nonuniform pore size as the void spacing between or within the skeleton is not uniform as shown for example in FIG. 5; where the array separation can be chosen, for example, based on differential deposition rates of the deposited material in different regions of the skeleton such as resulting from a geometry of the deposition chamber). In variants where the spacing between the skeleton structures are nonequidistant, the spacing can be different in one or more directions. As a first specific example, the spacing can be uniform in a first direction and nonuniform in a second direction. As a second specific example, the spacing can be nonuniform in a first and a second direction. As a third specific example, the skeleton can be associated with a lattice constant (e.g., a vector with 2 components) where one of the components can be a constant and the second can be nonconstant (e.g., according to a function of position, nearest neighbors, etc.). As a fourth specific example, the skeleton can be associated with a lattice constant (e.g., a vector with 2 components) both components can be nonconstant (e.g., according to a function of position, nearest neighbors, etc.). However, the skeleton can otherwise be arranged.

The spacing between skeleton structures (e.g., between nearest neighboring structures of a similar structure, between pillars, parallel members, etc.) can depend on the deposited material deposition rate, deposition parameters, target object quality, target fabricated material properties (e.g., where the skeleton can impart one or more property on the final fabricated material), target fabricated material composition (e.g., volumetric composition, atomic composition, etc.), a mean free path of chemical precursors for the deposition of the deposited material, a sticking probability of the deposition precursors on the skeleton, a reaction probability of the deposition precursors, a temperature of the deposition, a pressure of the deposition, a precursor identity, and/or other suitable properties. As such, the spacing (e.g., center to center spacing, wall-to-wall spacing, wall-to-center spacing, center to wall spacing, etc.) is typically between 1 μm and 10 mm (e.g., 10 μm, 15 μm, 20 μm, 25 μm, 50 μm, 100 μm, 150 μm, 200 μm, 250 μm, 500 μm, 1 mm, 1.2 mm, 1.5 mm, 2 mm, 2.5 mm, 5 mm, values or ranges therebetween, etc.). Additionally or alternatively, a spacing between skeleton structures (e.g., members thereof) can be 2-times, 3-times, 5-times, 10-times, 20-times, 50-times, 100-times, 1000-times, and/or other multiple of a size of the skeleton structure (e.g., member thereof).

The skeleton structures (or members thereof) are typically cylindrical (e.g., have a circular or elliptical cross-section in a plane perpendicular to a long axis of the structure) or spherocylindrical (e.g., capsule shape, stadium of revolution, frustosphereocylindrical, etc. such as having a stadium or half-stadium cross-section along a plane parallel to a long axis of the skeleton). However, the skeleton structures (or members thereof) can additionally or alternatively polyhedral, hemicylindrical, prismatic, pyramidal, hemispherical, and/or can have any suitable shape or geometry.

A characteristic size of the skeleton structures (or members thereof) in a short axis (e.g., perpendicular to a growth axis of the skeleton structure when the skeleton structure is generated by a growth mechanism), such as a radius or diameter of a cylindrical skeleton structure, is typically between about 1 μm and 1 mm (e.g., 5 μm, 10 μm, 20 μm, 50 μm, 100 μm, 150 μm, 200 μm, 500 μm, values or ranges therebetween). However, the characteristic size of the short axis may be outside this range (e.g., when greater time for skeleton formation is allowed such as to permit formation of larger fabricated materials).

A characteristic size of the skeleton structures (or members thereof) in a long axis (e.g., parallel to a growth axis of the skeleton structure when the skeleton structure is generated by a growth mechanism), such as a height of a cylindrical skeleton structure, is typically less than about 5 mm (e.g., 100 μm, 150 μm, 200 μm, 500 μm, 1000 μm, 1500 μm, 2000 μm, 2500 μm, 3000 μm, 4000 μm, values or ranges therebetween, etc. where the height is typically limited by the material's ability to remain freestanding without breaking). However, the characteristic size of the long axis may be outside this range (e.g., a taller cylinder may be possible with thicker skeleton structure).

The skeleton is typically made of carbon (e.g., sp2 carbon, graphite carbon, polymers, amorphous carbon, diamond, etc.). However, the skeleton can additionally or alternatively be made of boron, alkali metals, alkaline earth metals, transition metals, refractory metals, refractories, ceramics, and/or other suitable materials (e.g., where the material of the skeleton can be selected based on target properties of the fabricated materials, based on target skeleton structure or size, based on predicted time for growth of a skeleton structure, etc.). In some variants, any deposited material could be used to form a skeleton (where the skeleton and the deposited material can be the same, such as a carbon-carbon composite, or different, such as a metal matrix composite or ceramic matrix composites).

The skeleton is typically formed on a substrate. However, the skeleton can be freestanding (e.g., the substrate and skeleton can be the same). The substrate is preferably made from a material that can readily separate from the fabricated material (e.g., mechanically removed, chemically removed, etc.), can withstand a laser-controlled deposition process, can absorb light of a specific wavelength (e.g., matching a wavelength of a laser), form bonds with the skeleton material, has a low thermal conductivity (e.g., to minimize conduction of heat away from target hot spots), and/or can have other suitable properties. In different variants, the substrate can either act as a site for growth of deposited material or can act as a poor site for growth of deposited material. Examples of substrates include carbonized paper, graphite, titanium, carbidized titanium, alumina-silicate ceramics, and/or other suitable materials (e.g., skeleton materials or deposited material can be particularly beneficial).

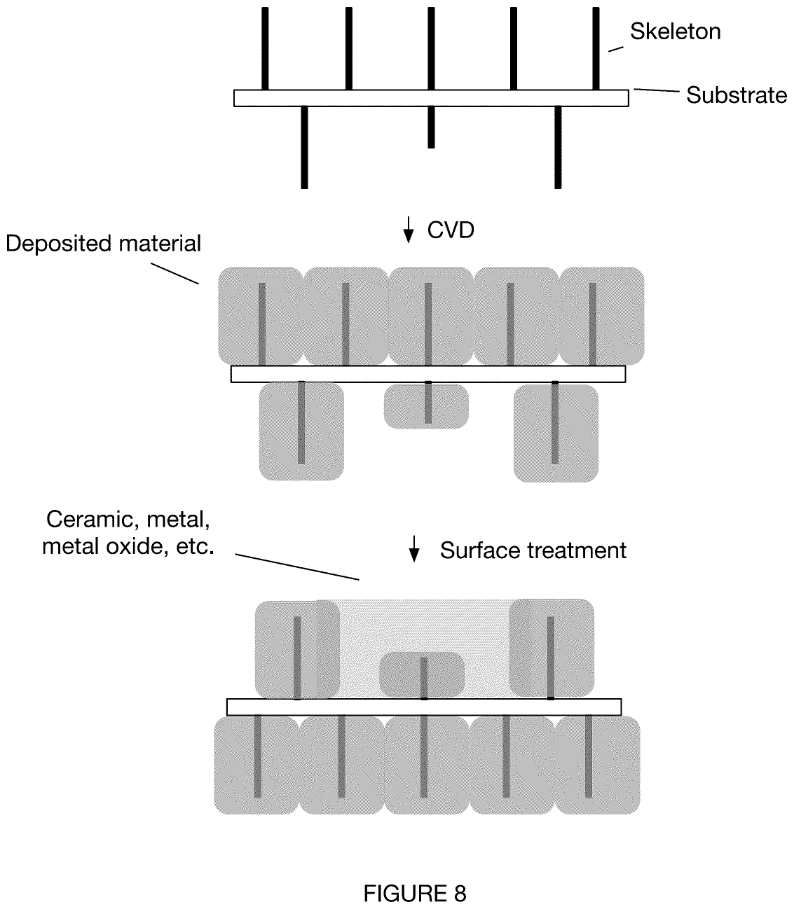

The skeleton can be grown on a single side (e.g., single broad face) of a substrate and/or on a plurality of broad faces of the substrate (as shown for example in FIG. 8).

The one or more deposited materials can function to provide a target property to an end fabricated material, can function to form a fabricated material, and/or can otherwise function. The deposited materials are preferably refractories and/or refractory metals. However, in some variants, one or more deposited materials can include non-refractory metals and/or alloys thereof or other readily machinable materials (particularly but not exclusively to form intermediate layers encased within another deposited material such as to produce desired target properties).

In some embodiments, the deposited materials can exclude oxides (e.g., metal oxides, transition metal oxides, etc.). However, deposited materials can include oxides (e.g., an outmost oxide layer can be deposited rather than formed from oxidation of an outermost deposited layer, an oxide layer can be deposited between deposited materials and/or the skeleton such as to act as a protectant against reactions between layers, the deposited material can be an oxide, etc.). In other variations, an oxide layer can be formed on the deposited materials (e.g., by oxidizing the deposited materials during or after deposition).

Specific examples of deposited materials include (but are not limited to): graphite, amorphous carbon, glassy carbon, pyrolytic carbon, diamond, carbides (e.g., silicon carbide, boron carbide, titanium carbide, zirconium carbide, hafnium carbide, vanadium carbide, niobium carbide, tantalum carbide, chromium carbide, tungsten carbide, molybdenum carbide, etc.), refractory metals (e.g., titanium, vanadium, chromium, zirconium, niobium, molybdenum, ruthenium, rhodium, hafnium, tantalum, tungsten, rhenium, osmium, iridium, alloys therebetween), sulfides (e.g., cerium sulfide, gold sulfide, etc.), nitrides (e.g., boron nitride, titanium nitride, silicon nitride, zirconium nitride, tungsten nitride, vanadium nitride, tantalum nitride, niobium nitride, scandium nitride, yttrium nitride, chromium nitride, molybdenum nitride, etc.), metal-containing polyatomics (e.g., aluminates such as calcium aluminate; titanates such as bismuth titanate, calcium titanate, barium titanate, iron titanate, etc.; germanates such as bismuth germanate, sodium germanate, etc.; etc.), oxynitrides (e.g., silicon oxynitride, aluminium oxynitride, lithium silicon oxynitride, sodium silicon oxynitride, potassium germanium oxynitride, phosphorous oxynitride, chromium oxynitride, zinc oxynitride, titanium oxynitride, vanadium oxynitride, zirconium oxynitride, niobium oxynitride, molybdenum oxynitride, ruthenium oxynitride, rhodium oxynitride, hafnium oxynitride, tantalum oxynitride, tungsten oxynitride, rhenium oxynitride, osmium oxynitride, iridium oxynitride, etc.), silicides (e.g., nickel silicide, sodium silicide, magnesium silicide, platinum silicide, titanium silicide, vanadium silicide, chromium silicide or chromium disilicide, zirconium silicide, niobium silicide, molybdenum silicide or molybdenum disilicide, ruthenium silicide, rhodium silicide, hafnium silicide, tantalum silicide, tungsten silicide or tungsten disilicide, rhenium silicide, osmium silicide, iridium silicide, neptunium silicide, etc.), carbonitrides (e.g., titanium carbonitride, vanadium carbonitride, chromium carbonitride, zirconium carbonitride, niobium carbonitride, molybdenum carbonitride, ruthenium carbonitride, rhodium carbonitride, hafnium carbonitride, tantalum carbonitride, tungsten carbonitride, rhenium carbonitride, osmium carbonitride, iridium carbonitride, etc.), borides (e.g., scandium dodecaboride, yttrium boride, titanium boride, zirconium boride, hafnium boride, niobium boride, tantalum boride, chromium boride, molybdenum boride, tungsten boride, rhenium boride, ruthenium boride, osmium boride, iron tetraboride, cobalt borides, nickel boride, lanthanum boride, cerium boride, samarium boride, europium boride, erbium boride, trinickel boride, magnesium boride, calcium boride, strontium boride, barium boride, silicon boride, aluminium boride such as aluminium dodecaboride, etc.), oxycarbides, oxyborides, oxysilides, borocarbide, borosilide, borosulfide, and/or combinations thereof.

In variants that include a plurality of deposited materials, each deposited material preferably has a matching coefficient of thermal expansion (CTE). Matching coefficient of thermal expansion can depend on an application, temperatures that the materials will be exposed to, fabricated material size, number of interfaces (e.g., number of deposited materials, number of different materials, etc.), a deposition temperature, and/or can otherwise be determined. As a specific example, the coefficient of thermal expansion between adjacent deposited materials and/or between a deposited material and a skeleton material is preferably less than about 5 ppm/° C. However, other suitable differences in coefficient of thermal expansion can be realized (e.g., leveraging intermediate layers to mitigate a large CTE difference between materials).

In some variants, a plurality of deposited materials can be leveraged to provide engineered anisotropic properties for the fabricated object. For example, anisotropic mechanical toughness (e.g., Young's modulus, ductility, yield strength, creep rate, elastic constants, stiffness, etc.), ion and/or molecular transport (e.g., electrical conductivity, electrically insulating, ionically conductive, ionically insulating, etc.), and/or other suitable properties. As a specific example (as shown in FIG. 10), a first material and a second material can be deposited on a skeleton where the first material can have or impart the anisotropic property (e.g., a specific electrically conductive path through a material can be formed by depositing an electrically conductive material on the skeleton to a thickness where the first deposited material does not contact other first deposited material followed by a second deposited material that does contact other second deposited material between skeleton members, where the second deposited material does not have the property or has a lower value of the property). In some variants, the anisotropic properties can be a result of the skeleton material presence in the deposited material (as opposed to or in addition to deposited material(s)).

### 5. Method

As shown in FIG. 11, a method for making a fabricated material can include: receiving a skeleton S100, depositing material on the skeleton S200, and optionally processing the fabricated material S300. The method preferably functions to produce the fabricated material (e.g., the material of FIG. 1, a material as described above, a material similar to that in FIG. 1 that includes a plurality of deposited materials, a material derived from the material in FIG. 1 such as an alloy formed from the material in FIG. 1, etc.).

All or portions of the method can be performed in real time (e.g., responsive to a request), iteratively (e.g., S100 and S200 can be performed iteratively to form a skeleton grow material on the skeleton and subsequently grow another skeleton on the existing material to facilitate further growth of material; S100, S200, and S300 can be performed iteratively to process intermediate layers before depositing further layers of material for instance to improve an adhesion of the additional deposited material or additional skeletons; etc.), concurrently, asynchronously, periodically, and/or at any other suitable time. All or portions of the method can be performed automatically, manually, semi-automatically, and/or otherwise performed.

S100 and S200 are preferably performed within growth chamber(s). S100 (when S100 includes forming the skeleton) and S200 can be performed in the same or different growth chamber. For instance, S100 can be performed in a laser-assisted chemical vapor deposition chamber (e.g., a reactor as described in PCT Application Number PCT/US2023/034308 filed 2 Oct. 2023, U.S. Provisional Application No. 63/432,139 filed 13 Dec. 2022, and/or U.S. Provisional Application 63/378,357 filed 4 Oct. 2022), a thermally-assisted chemical vapor deposition chamber (e.g., a CVD chamber that includes a local heating element, local heating source, etc. that can provide local portions of increased temperature where deposition occurs), and/or other suitable growth chambers and S200 can be performed in a CVD growth chamber (e.g., tube furnace, furnace, plasma chamber, etc.).

The volume, configuration, operating conditions, and other properties of the growth chamber(s) can depend on the fabricated material (e.g., skeleton, deposited material, size of the target object, etc.).

Operating parameters for the growth chamber include: precursor(s), temperature, pressure, growth time, plasma presence, and/or other suitable properties. The operating parameters are typically tuned based on the target material to deposit (e.g., for the skeleton material, for the infill material, for the deposited material, etc.). However, the same operating parameters can be used for many different target materials. For example, the temperature (e.g., local temperature resulting from laser heating, local heating mechanism, substrate temperature, skeleton temperature, precursor temperature, etc.; growth chamber temperature; etc.) is typically between about 500° C. and 4000° C.; and the pressure is typically between 10 torr and 7600 torr (e.g., about 10-760 torr for S200, about 1-10 bar in S100, etc.). The growth rate for material is typically between about 1 μm/hr and 500 mm/hr (e.g., 2 μm/hr, 5 μm/hr, 10 μm/hr, 15 μm/hr, 20 μm/hr, 50 μm/hr, 100 μm/hr, 150 μm/hr, 200 μm/hr, 250 μm/hr, 500 μm/hr, 1 mm/hr, 2 mm/hr, 5 mm/hr, 10 mm/hr, 15 mm/hr, 20 mm/hr, 50 mm/hr, 100 mm/hr, 150 mm/hr, 200 mm/hr, 250 mm/hr, 500 mm/hr, values or ranges therebetween, etc.). As such the growth time can vary from 1 minute to 1000 hours (and/or can exceed 1000 hours or be less than 1 minute depending on a target size and growth rate).

Exemplary precursors that can be used for carbon deposition (e.g., for graphite, to provide carbon for carbide formation, etc.) include: alkanes (e.g., methane, propane, etc.), alkynes (e.g., acetylene, propyne, etc.), alkenes (e.g., propylene, ethylene, etc.), aromatics (e.g., benzene, naphthalene, toluene, etc.), combinations thereof, and/or other suitable hydrocarbons. Exemplary precursors that can be used for diamond deposition include: hydrogen (H) atoms (e.g., to suppress formation of graphite phase), hydrocarbons (e.g., methane, acetylene, other hydrocarbons used to deposit carbon, etc.), halogens (e.g., fluorine, chlorine, bromine, iodine, etc. which may be beneficial for lowering processing temperature), dopants (e.g., colorants such as boron or transition metal precursors which can provide inclusions improving optical properties, imparting a target color, etc.), and/or other suitable precursors. Exemplary precursors for silicon carbide include: organosilicon compounds (e.g., methyltrichlorosilane, tris(trimethylsilyl) silane, etc.), inorganic silicon (e.g., silicon tetrachloride, silane, silicon tetrabromide, silicon tetraiodide, etc.), hydrocarbons (e.g., alkanes such as methane, propane, etc.; alkynes such as acetylene, propyne, etc.; alkenes such as propylene, ethylene, etc.; aromatics such as benzene, naphthalene, toluene, etc.; combinations thereof; etc.), combinations thereof, and/or other suitable precursors. Exemplary precursors for refractory metals (M) include: chlorides (e.g., MClₓ such as TiCl₃, TiCl₄, MoCl₅, NbCl₅, TaCl₅, WCl₆, etc.), bromides (e.g., MBrₓ such as TiBr₃, TiBr₄, MoBr₅, NbBr₅, TaBr₅, WBr₆, etc.), iodides (e.g., MIₓ such as WI₆, ZrI₃, ZrI₄, HfI₃, HfI₄, etc.), fluorides (MFₓ such as WF₆), metal-organics, carbonyls (M (CO)ₓ such as Mo(CO)₆, W(CO)₆, etc.), and/or other suitable species. Exemplary precursors for boron (and/or boron inclusion) include: boranes (e.g., di-borane), borohalides (e.g., boron trichloride, boron trifluoride, boron tribromide, boron triiodide, etc.), and/or other suitable boron sources (e.g., organoborides). Exemplary precursors for nitrogen inclusion include: nitrogen (N₂), ammonia, organonitrogen compounds (e.g., amines, amides, nitroso, imines, etc.), and/or other suitable nitrogen precursors. To form binary, trinary, quaternary and/or higher order mixtures of materials, precursors from the above can be combined. As an illustrative example, titanium carbide can be deposited by using a precursor that includes a combination of one or more titanium precursors and one or more carbon precursors (e.g., in a ratio that depends on the reaction rate for the respective precursors, target composite composition, mean free path length for the precursors, pressure, temperature, etc.). Similar combinations (and considerations) apply to form other materials. The precursors can optionally include a carrier gas (e.g., an inert gas such as a noble gas like He, Ne, Ar, Kr, Xe, etc.; a carrier that does not react in the operating conditions such as carbon dioxide or nitrogen; etc.), scavenger(s) (e.g., hydrogen gas which can function to scavenge counterions that are not deposited such as to capture chlorine atoms in chlorine processes where scavengers are typically provided in excess in the variants that include them), and/or other suitable species.

In variants that leverage laser-assisted deposition, many types of lasers may be suitable for growth of the skeleton, including: 1D or 2D arrays of edge-emitting laser diodes whose output powers may be individually addressable, and whose optical spots may be reimaged into the plane of growth using a lens system (and optional apertures or reimaging optics to modify mode quality); arrays of vertical-cavity surface emitting lasers reimaged into the growth chamber with a lens system; high-power individual lasers whose beams are rapidly redirected in space (e.g., by MEMS mirrors, acousto-optic modulators, spatial light modulators, etc.) to produce suitable target (e.g., local) temperatures in the growth chamber; high-power lasers whose outputs are shaped via spatial light modulators, digital micromirror devices, holographic elements, beamlet arrays, etc.; and/or other suitable laser systems can be used. The laser can operate in continuous-wave and/or pulsed operation modes. When operated in a pulsed mode, the pulse repetition rate is often between 10 Hz and 100,000 Hz. However, any suitable pulse repetition rate can be used. When operated in a pulsed mode, the duty cycle is often between 1% and 90%. However, any suitable duty cycle can be used. The wavelength of the laser is preferably absorbed by the substrate. However, other suitable wavelengths can be used. The wavelength can also impact the feature size of the skeleton (e.g., in the best-case situation, a diffraction limited spot could be formed resulting in a skeleton characteristic size approximately equal to the diffraction limited spot). The intensity of the laser is preferably sufficient to achieve a target local temperature (e.g., 2000° C.-3000° for carbon deposition as a specific example, other temperatures can be achieved for other materials). The intensity can depend on the wavelength of the laser, substrate material (e.g., absorption coefficient of the substrate at the laser wavelength, thermal diffusion constant, etc.), and/or other suitable properties.

Receiving a skeleton S100 functions to access a skeleton (e.g., scaffold, space frame, etc.) that can be used for material deposition thereon. The skeleton is preferably a skeleton as described above. However, other suitable skeleton(s) can be used (e.g., foams, meshes, fiber, etc.). The skeleton (but not necessarily the material thereof) is preferably porous with a high void volume (e.g., 90-99.9999% void volume). However, the skeleton can have a lower void volume. The void volume can be isotropic (e.g., pore size and/or shape are substantially constant along the skeleton) and/or anisotropic (e.g., pore size, pore shape, etc. vary within the skeleton).

Receiving the skeleton can include forming the skeleton. The skeleton can be formed using chemical vapor deposition, physical vapor deposition, moulding, machining, automated fiber placement, filament winding, lanxide processing, tufting, z-pinning, casting, centrifugal casting, braiding, continuous casting, filament winding, press moulding, transfer moulding, pultrusion moulding, slip forming, vacuum infusion, wet lay-up, compression moulding, and/or using other suitable methods and/or processes.

As an illustrative example, spatially controlled deposition can be performed, where deposition of a precursor (e.g., precursor fluid such as precursor liquid, precursor gas, precursor plasma, etc.) to form the skeleton material only occurs proximal to a desired location. As a specific example of this illustrative example, laser-controlled deposition can be used to result in deposition of material proximal to predetermined locations. Other optical, thermal, electrical, fluid flow control, and/or mechanisms can additionally or alternatively be leveraged to control the spatial deposition and/or growth of the skeleton.

In an illustrative example of laser-mediated skeleton formation, a substrate for the deposition can be placed inside a growth chamber. The growth chamber can include an optical path between one or more laser modules and the substrate. The growth chamber can be filled with a precursor fluid (e.g., a hydrocarbon gas, a suitable precursor fluid from the precursor fluids as used in S200, etc.) under appropriate conditions (temperature, pressure, precursor flow rate, etc.). One or more laser spots can be focused on the substrate, creating local hot spots (e.g., regions with greater temperatures such as temperatures locally exceeding 500° C., 750° C., 1000° C., 1500° C., 2000° C., 2500° C., 3000° C., 3500° C., 5000° C., etc.) that lead to local skeleton deposition on the substrate (e.g., via thermally induced pyrolysis reactions, or other chemical reactions). The temperature of these hot spots can depend on substrate properties, laser properties (e.g., optical intensity, wavelength, polarization, mode, etc.) and/or other suitable properties. The properties can be tuned (e.g., selected) to achieve a desired temperature for growth (e.g., 1000 to 3000 degrees Celsius to deposit solid carbon, other temperatures for other materials). The optical focus can be changed (e.g., by translating the laser module, by translating focusing optics within the laser module, by translating the substrate and growing skeleton, etc.) such as to maintain a hot spot proximal to a tip of the growing skeleton deposits. As an illustrative example, fibrous columns can be grown perpendicularly to the substrate plane (e.g., z direction as shown for instance in FIG. 2a). In variations of this illustrative example, more complex (e.g., curved columnar structures, trussed structures, etc.) can be grown by sweeping out different spatial paths with the laser spot (e.g., movement in x and z as shown for instance in FIG. 2b).

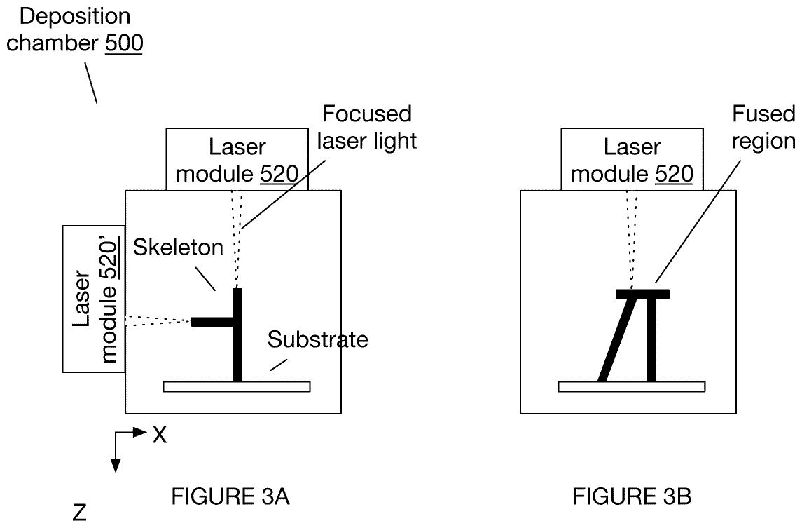

A focused laser beam will typically induce solid growth along the axis of the focusing cone of light (e.g., along the z direction in FIG. 2A; growth away from this axis tends to be suppressed because these regions are not as intensely heated by the laser beam). However, growth may occur in a transverse direction (e.g., resulting from heat propagation within the depositing material). Additionally or alternatively, an angle of laser incidence during growth can be changed (e.g., using additional laser modules, using beam steering optics, translating and/or rotating the laser module, translating and/or rotating the substrate and skeleton growing thereon, etc.). As an illustrative example, a T-shaped structure can be fabricated by first growing a column on the substrate with a laser incident normal to the substrate, and subsequently growing a column perpendicular (and attached to the column), for instance by using a laser incident parallel to the plane of the substrate (e.g., as shown for example in FIG. 3A). Varying the angle of incidence can additionally or alternatively be useful in the process of fusing two adjacent members (e.g., columns, rows, pillars, etc.). For instance, fusion of members can be achieved by dwelling one or more laser beam in the vicinity of both columns, illuminating appropriate surfaces, with the gas-phase deposition thickening the two columns until they merge (as shown for instance in FIG. 3B). However, fusion can otherwise be achieved.

Using the above manipulations and others, it is possible (in variants that leverage laser-assisted deposition) to produce straight, curved, or sharply angled members (e.g., columns, pillars, etc.), as well as join (e.g., fuse, merge, connect, etc.) or split (e.g., separate, disconnect, etc.) members (e.g., columns, pillars, etc.). Arbitrary three-dimensional structures can be deposited using these techniques. Many other advantageous spatiotemporal manipulations of the laser-controlled heat patterns are also possible (for example according to processes as described in PCT Application Number PCT/US2023/034308 filed 2 Oct. 2023, U.S. Provisional Application No. 63/432,139 filed 13 Dec. 2022, and/or U.S. Provisional Application 63/378,357 filed 4 Oct. 2022, each of which is incorporated in its entirety by this reference).

In some variants, the geometry of the skeleton can be optimized for the specific needs of downstream matrix infiltration. One example of a skeleton that is optimized for structural support can be skeleton that includes a network of pillars and trusses (e.g., where each pillar or truss can be referred to as a member such as a cubic lattice of members such as shown for example in FIG. 4A, a cubic lattice of pillars as shown for example in FIG. 4B, a rectangular lattice of members, a hexagonal lattice of members, a circular lattice of members, etc.). A second example of a skeleton that is optimized for deposition of deposited material (e.g., to compensate for uneven deposition rates, to achieve a substantially uniform density fabricated object, etc.) can include spatial modulation of the skeleton (e.g., preform) porosity. Variations of the skeleton can have an engineered porosity of the skeleton to compensate for uneven deposition rates, to achieve substantially uniform density, and/or for other purposes. For instance, a larger pore size (e.g., spacing between members) can be used in regions of the skeleton which will thicken faster under isothermal deposition conditions (as shown for instance in FIG. 5). In another variation of the second example, specialized channels (possibly organized in a hierarchical manner) can be designed into the skeleton to modify (e.g., increase, decrease) deposition rate in certain areas of the object. A third example of a skeleton that is optimized for deposition of deposited material (e.g., to aid in liquid-phase infiltration) can be designed with structures (e.g., oriented structures) that help wick the liquid into certain regions of the object, and/or otherwise advantageously manipulate surface tension.

In some variants, the skeleton can be structured to enhance desired properties (e.g., mechanical, thermal, electrical, ionic, etc.) of the resulting fabricated material (e.g., composite). For example, to enhance tensile strength of a metal-matrix composite along an axis (or in some situations axes), the skeleton contain many members aligned along the axis (or axes). In another example, a similar arrangement (or an inverse arrangement) to the preceding example can be used to enhance (or decrease) thermal, electrical, and/or ionic conductivity along one or more axes. Note that while reference is made to axes, these properties can be more generally along any specified path made up of skeleton material. As another example, a skeleton can be structured to enhance bonding between regions of different chemical makeup. For instance, to strengthen the bond between a metal-rich region and a carbide-rich region in a composite formed on a carbon skeleton, the skeleton can contain many columnar elements extending from the carbide-rich region into the metal-rich region.

However, a skeleton can otherwise be formed.

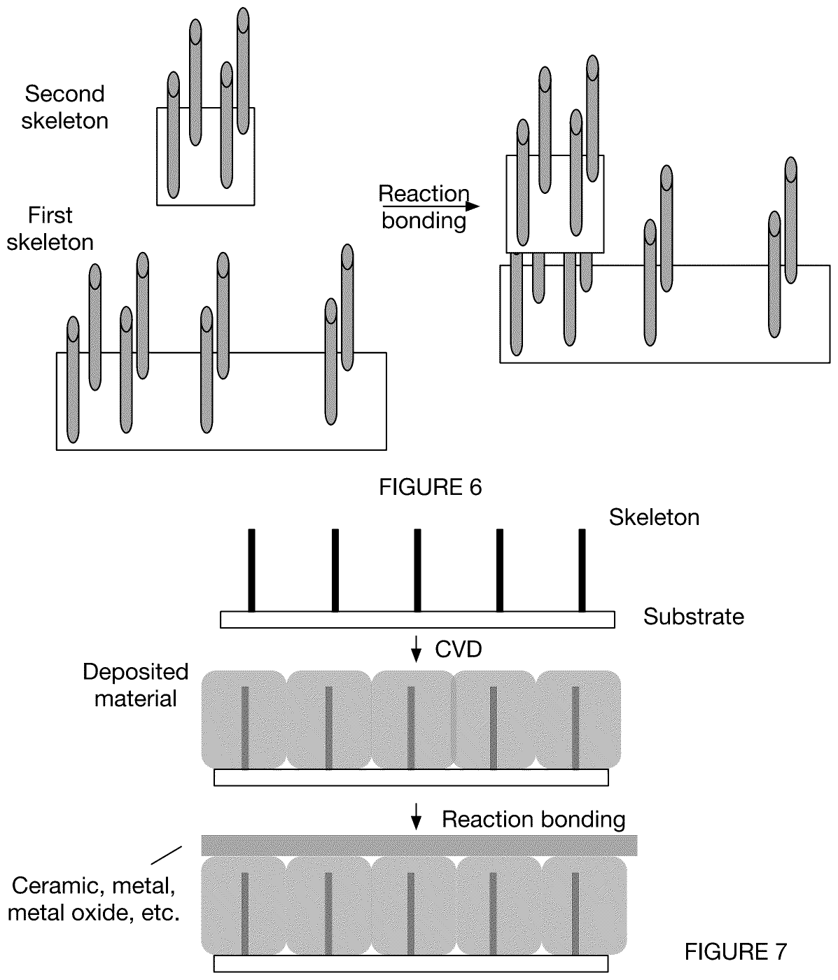

In some variants (as shown for instance in FIG. 6), a plurality of skeletons can be received. In these variants, each of the plurality of skeletons can be connected (e.g., in contact, bonded, etc.) to one another. For example, a first skeleton can be reaction bonded to a second skeleton to form a total object skeleton for the formation of an object.

Depositing material on the skeleton S200 functions to infiltrate the skeleton with deposited material (e.g., matrix material, infill, etc.) such as to fill void space defined between members of the skeleton (and/or direct growth directly onto the skeleton). S200 is typically performed in a separate growth chamber from S100, however, S200 and S100 can be performed in the same growth chamber. Typically, the operating parameters (for growth of deposited material as in S200) are balanced to achieve a mean free path of the precursors before deposition that is less than the spacing between members of the skeleton (e.g., when members are separated by 100 μm, the mean free path of precursor before depositing is between 1 μm and 100 μm).

The deposited material(s) can be added to the skeleton using chemical vapor deposition, physical vapor deposition, moulding, machining, automated fiber placement, filament winding, lanxide processing, tufting, z-pinning, casting, centrifugal casting, braiding, continuous casting, filament winding, press moulding, transfer moulding, pultrusion moulding, slip forming, vacuum infusion, wet lay-up, compression moulding, and/or using other suitable methods and/or processes.

As the deposited material is grown on the skeleton, void spaces within the fabricated material can be presented in the finished process. As shown schematically in FIG. 12 for a pillar-type skeleton, the void spaces typically have a shape resulting from intersection of a plurality of cylindrical segments (e.g., circular cross sections) such as arbelos, bankoff circle, triplet circle, quartet circle, and/or other similar shapes. However, the shape and/or size of the voids in the resulting fabricated material (e.g., within the deposited material) can have other shapes (e.g., based on a skeleton geometry). In some variations, S200 can change process parameters to improve infiltration into the void spaces to minimize their inclusion (e.g., by changing precursor spatial distribution, mean free path of the precursors, etc.).

The deposited materials (e.g., matrix) may be deposited using precursors in vapor phase and/or liquid phase.

As a first illustrative example, a carbon skeleton can be thickened into a dense carbon-carbon composite via a chemical vapor infiltration (e.g., CVD) such as pyrolysis of gaseous or liquid hydrocarbons (e.g., methane) in an oven at suitable temperatures (e.g., around 1000° C., 2000° C., 3000° C., etc.) and pressures (e.g., sub-atmospheric). Heating of the relevant components in the oven (e.g., the hot surfaces of the oven, the parts to be thickened, the precursors, etc.) can be accomplished using any suitable means of delivering energy (e.g., resistive heating, combustion of fuels, microwave irradiation, induction heating, laser heating, etc.). Alternatively, or additionally, the skeleton can be thickened by liquid-phase infiltration and pyrolysis of pitch, lignin, plastics, and/or other carbon-containing materials.

As a second illustrative example, “reaction bonding” schemes can be used to add deposited material. For instance, a carbon skeleton, which may have previously been partially or fully densified into a carbon-carbon composite (e.g., according to the first illustrative example), can be exposed to liquid silicon (e.g., a silicon solution, melted silicon, etc.). Then a reaction can bind the silicon and carbon into silicon carbide (SiC), silicon-silicon carbide (Si—SiC), and/or carbon-silicon carbide (C—SiC) composite (e.g., depending on the elemental composition—where all can be present at the same time depending on anisotropies in the inclusion). Forming a composite such as C—SiC in selected areas of the object can result in desirable features such as higher durability, improved chemical resistance, altered friction properties, and/or other suitable features (e.g., that can be anisotropic as a result of being formed in only target regions, that can be substantially isotropically distributed, etc.). Reaction bonding with liquid silicon can additionally or alternatively be used to bond two or more skeletons and/or densified composites (e.g., skeletons that include deposited material) together. Bonding two or more skeletons and/or densified composites can be advantageous for building three-dimensional structures by stacking multiple skeletons into a “2.5D” part (as shown for example in FIG. 6). Alternatively, if a SiC matrix is primarily desired, it is possible to deposit SiC directly from the vapor phase using a vapor-phase infiltration and pyrolysis of a precursor such as methyltrichlorosilane (MTS), hexamethyl disilazane (HMDS), tetramethyl silane, and/or other suitable precursors (e.g., as described above). As another variation (as shown for instance in FIG. 7), a ceramic, metal, metal oxide, and/or other suitable material can be reaction bonded to a surface of the deposited material (e.g., to create a nonstick, scratch resistant, etc. coating).

As a third illustrative example, a carbon skeleton can be infiltrated with other liquid metals. For instance, liquid titanium can react with a carbon skeleton to form titanium carbide (TiC); the presence of excess carbon can result in C—TiC composites, while excess titanium can result in Ti—TiC composites. Infiltration of C—SiC composites with aluminum can result in a composite of aluminum, carbon, and SiC (inclusive of C—SiC and Si—SiC) that can retain chemical and/or mechanical properties of SiC while also achieving higher durability. Infiltration of carbon skeletons or C≡C composites with copper may result in a near-net-shape part with enhanced electrical conductivity. However, other suitable metals can be used to infiltrate a carbon skeleton.

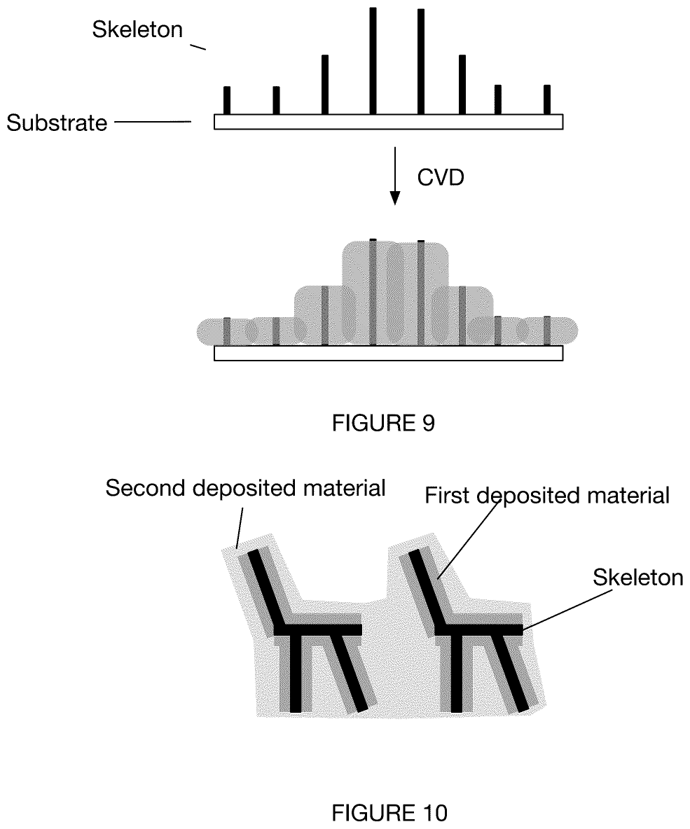

As a fourth illustrative example (e.g., for the formation of diamond), a skeleton can optionally be seeded with diamond (e.g., by submersion in a solution containing nanodiamonds, or by other methods) and subsequently placed in a CVD reactor for diamond growth. The CVD reactor may use any diamond growth scheme (e.g., hot filament, direct-current plasma, microwave plasma, inductively coupled plasma, plasma torch, etc.) using any of suitable precursors (e.g., hydrogen, methane, ethanol, carbon precursors, etc.). By varying the CVD conditions (e.g., by varying process temperatures, injecting impurity gases, changing seeding approaches, etc.), physical properties (e.g., grain size, fracture toughness, hardness, strength, transparency, color, opacity etc.) of the diamond matrix can be tailored. The deposited CVD diamond preferably coats the surfaces of the skeleton in such a way that the composite of the desired three-dimensional shape is ultimately formed. For instance, diamond deposited on different filamentary surfaces may ultimately merge into a unified material (as shown for example in FIG. 9—similar is true for other deposited materials as well). In a hot-filament reactor, the growth rate can be faster on the portions of the skeleton that are nearer to the filament; in such a situation it may be appropriate for the skeleton to be more porous in regions that will be held closer to the filament. In some variations of this specific example, it can be advantageous to remove the skeleton from the growth substrate prior to CVD diamond deposition (e.g., because the substrate is not stable in the diamond growth conditions). Additionally or alternatively, the skeleton and/or substrate can be coated with another material (e.g., silicon carbide deposited via CVD, additional pyrocarbon deposited via CVD, etc.) prior to CVD diamond deposition.

These illustrative examples are not intended to be limiting but rather to showcase exemplary approaches that a person can apply to other applications as realized by this application.

Optionally processing the fabricated material S300 functions to finish the fabricated material and/or object derived therefrom. For example, S300 can function to increase a density of the resulting material (e.g., by closing or removing void space or pores resulting from the deposited materials growth process such as those pores as shown in FIG. 12), form the fabricated material into a net-shape, improve a surface finish of fabricated material (e.g., form planar broad faces of the surface of the fabricated material), convert a composite fabricated material into a compound or alloy, removing a substrate and/or skeleton from a material, and/or can otherwise function.

S300 can include one or more of infiltrating (e.g., to fill void spaces remaining after S200, to fill interstitials, etc.), sintering (e.g., where a sintering temperature, time, environment, etc. can depend on the material to be sintered such as pressure-assisted sintering, spark plasma sintering, hot isostatic pressing, microwave sintering, reactive sintering, liquid-phase sintering, field-assisted sintering, selective laser sintering, freeze sintering, flash sintering, self-propagating high temperature synthesis, induction sintering, etc.), wafer bonding processes (e.g., direct bonding, surface activated bonding, plasma activated bonding, anodic bonding, eutectic bonding, glass frit bonding, adhesive bonding, thermocompression bonding, reactive bonding, transient liquid phase diffusion bonding, atomic diffusion bonding, etc.), surface passivating (e.g., oxidizing, nitridizing, boronizing, oxynitridizing, carbidizing, oxycarbidizing, anodizing, bluing, chromate conversion coating, phosphate conversion coating, Parkerizing, etc. an exposed surface of the fabricated material, a skeleton material, etc.), skeleton removal (e.g., via etching, chemical milling, etc.), substrate removal (e.g., via etching, chemical milling, mechanical separation, cutting, shearing, melting, vaporizing, etc.), surface finishing (e.g., cutting, grinding, polishing, roughening, blanching, burnishing, calendering, case hardening, glazing, cladding, corona treating, electroless plating, electroplating, galvanizing, gilding, knurling, painting, peening, laser peening, pickling, plasma spraying, coating, electroplating, electrophoric deposition, mechanical plating, sputter depositing, chemical vapor depositing, physical vapor depositing, vacuum plating, abrasive blasting, chemical-mechanical planarization, electropolishing, electrochemical machining, flame polishing, gas cluster ion beam, grinding, etching, laser ablation, laser engraving, linishing, magnetic field-assisted finishing, tumble finishing, vibratory finishing, shot peening, buffing, lapping, superfinishing, etc.), densifying the fabricated material (e.g., increasing a mass per unit volume averaged over a volume larger than a volume of a repeating unit of the skeleton, increasing a density of the deposited material in a randomly selected volume of 1 cubic nanometer within the object, etc.), and/or other suitable processes can be performed.

As a first illustrative example, a titanium-carbon composite (e.g., titanium deposited on a carbon skeleton, titanium carbide deposited on a carbon skeleton, titanium carbide deposited on a titanium skeleton, titanium carbide deposited on a titanium carbide skeleton, titanium carbide deposited on a carbon skeleton, carbon deposited on a titanium skeleton, carbon deposited on a titanium carbide skeleton, multilayer deposition including combinations of titanium and carbon in various layers, etc.) can be densified and/or converted to an alloy using hot isostatic pressing. Illustrative Examples

In a first illustrative example a method can enable rapid fabrication of net-shape or near-net-shape composite and/or alloy objects, which may reduce the minimum selling price of finished goods. Consider for instance a rectangular prism of carbon-carbon composite, 20 mm thick. A skeleton for such as part can include (e.g., consists of) pillars grown perpendicularly to a substrate at 20 mm length where the pillars are spaced on a hexagonal lattice in two dimensions with 1 mm separation between nearest neighbors. An average diameter of the pillars in this example can be about 20 μm. Owing to the simplicity of this skeleton, the pillars could be grown simultaneously by a laser head capable of casting as many spots as there are pillars in the skeleton. Assuming such a laser head, and assuming a typical growth rate of 0.1 mm/s for each pillar, the growth of the 20-mm-tall skeleton can be completed within about 200 seconds. The skeleton can then be thickened into a full composite by chemical vapor infiltration: for example, the skeleton may be placed into an oven flowing methane gas at modest pressure (e.g., 1-100 torr) with the skeleton held between about 1000-2500° C. (e.g., to achieve such temperatures, the oven and/or the skeleton itself may be heated by induction, microwaves, direct resistive heating, etc.). Under these conditions, it is possible to deposit high quality pyrolytic carbon layers on existing carbonaceous surfaces at rates on the order of 1 mm per hour. Since the spacing between pillars is about 1 mm, the lattice of pillars may thicken into a fully dense solid in less than an hour of furnace exposure. Since the growth of the skeleton can be completed in minutes, the total time spent producing the carbon-carbon composite can be less than one hour. Optional finishing of the part via reaction bonding with silicon to form a SiC layer, for instance, can also be completed in minutes.

In a second illustrative example, a method can comprise receiving a substrate comprising skeleton structures projecting out of a surface of the substrate; using a chemical vapor deposition process to deposit deposited material on the skeleton structures, wherein the deposited material deposits between (in some cases sealing, bridging, etc.) gaps between the skeleton structures; and removing the deposited material and skeleton structures from the substrate.

In variations of the second illustrative example or variations thereof, the deposited material can comprise at least one of graphite, diamond, silicon carbide, tungsten carbide, titanium carbide, tantalum carbide, titanium, molybdenum, niobium, tantalum, tungsten, zirconium, hafnium, boron, or titanium diboride. In variations of the second illustrative example or variations thereof, the skeleton structures are arranged with a porosity between 95% and 99.9%. In variations of the second illustrative example or variations thereof, a pore structure of the skeleton structures is nonuniform. In variations of the second illustrative example or variations thereof, the skeleton structures (e.g., members of the skeleton structures also referred to as a bone of the skeleton structure) can comprise a diameter between about 1 μm and about 200 μm. In variations of the second illustrative example or variations thereof, a center-to-center separation between nearest neighboring skeleton structures (nearest neighboring substantially parallel members of the skeleton structures) is between about 10 μm and about 1 mm. In variations of the second illustrative example or variations thereof, the skeleton structures can comprise pyrolytic carbon. In variations of the second illustrative example or variations thereof, the skeleton structures are formed by laser mediated deposition of the pyrolytic carbon from a carbon precursor. Variations of the second illustrative example or variations thereof, can further comprise finishing the deposited material. Variations of the second illustrative example or variations thereof, can further comprise densifying the deposited material. Variations of the second illustrative example or variations thereof, can further comprise alloying the skeleton and the deposited material (e.g., alloying titanium and carbon).

In a third illustrative example, a composite can comprise: a skeleton arranged at predetermined locations comprising skeleton material; and deposited material deposited on and around the skeleton wherein the deposited material forms a unified material. In variations of the third illustrative example or variations thereof, the skeleton material is different from the deposited material. In variations of the third illustrative example or variations thereof, the skeleton is at most about 5% (e.g., by volume) of the composition of the composite. In variations of the third illustrative example or variations thereof, the deposited material does not comprise an oxide. In variations of the third illustrative example or variations thereof, the deposited material can comprise at least one of graphite, diamond, silicon carbide, tungsten carbide, titanium carbide, tantalum carbide, titanium, molybdenum, niobium, tantalum, tungsten, zirconium, hafnium, boron, or titanium boride. In variations of the third illustrative example or variations thereof, the skeleton can comprise a plurality of free-standing members. In variations of the third illustrative example or variations thereof, the composite can further comprise a third deposited material wherein the third deposited material forms a layer grown on the skeleton material beneath the deposited material. In variations of the third illustrative example or variations thereof, the skeleton can comprise an interlocking structure. In variations of the third illustrative example or variations thereof, the skeleton can comprise carbon. In variations of the third illustrative example or variations thereof, the skeleton can be rigid. In variations of the third illustrative example or variations thereof, the skeleton can comprise a regular arrangement of skeleton members. In variations of the third illustrative example or variations thereof, a void fraction of the skeleton can be between 90% and 99.995%.

All or portions of the method can be performed by one or more components of the system, using a computing system, using a database (e.g., a system database, a third-party database, etc.), by a user, and/or by any other suitable system. The computing system can include one or more: CPUs, GPUs, custom FPGA/ASICS, microprocessors, servers, cloud computing, and/or any other suitable components. The computing system can be local, remote, distributed, or otherwise arranged relative to any other system or module.

Different subsystems and/or modules discussed above can be operated and controlled by the same or different entities. In the latter variants, different subsystems can communicate via: APIs (e.g., using API requests and responses, API keys, etc.), requests, and/or other communication channels.

Alternative embodiments implement the above methods and/or processing modules in non-transitory computer-readable media, storing computer-readable instructions that, when executed by a processing system, cause the processing system to perform the method(s) discussed herein. The instructions can be executed by computer-executable components integrated with the computer-readable medium and/or processing system. The computer-readable medium may include any suitable computer readable media such as RAMs, ROMs, flash memory, EEPROMs, optical devices (CD or DVD), hard drives, floppy drives, non-transitory computer readable media, or any suitable device. The computer-executable component can include a computing system and/or processing system (e.g., including one or more collocated or distributed, remote or local processors) connected to the non-transitory computer-readable medium, such as CPUs, GPUs, TPUS, microprocessors, and/or FPGA/ASIC. However, the instructions can alternatively or additionally be executed by any suitable dedicated hardware device.

Embodiments of the system and/or method can include every combination and permutation of the various system components and the various method processes, wherein one or more instances of the method and/or processes described herein can be performed asynchronously (e.g., sequentially), contemporaneously (e.g., concurrently, in parallel, etc.), or in any other suitable order by and/or using one or more instances of the systems, elements, and/or entities described herein. Components and/or processes of the preceding system and/or method can be used with, in addition to, in lieu of, or otherwise integrated with all or a portion of the systems and/or methods disclosed in the applications mentioned above, each of which are incorporated in their entirety by this reference.

As used herein, “substantially” or other words of approximation (e.g., “about,” “approximately,” etc.) can be within a predetermined error threshold or tolerance of a metric, component, or other reference (e.g., within 0.001%, 0.01%, 0.1%, 1%, 5%, 10%, 20%, 30% of a reference), or be otherwise interpreted.

As a person skilled in the art will recognize from the previous detailed description and from the figures and claims, modifications and changes can be made to the preferred embodiments of the invention without departing from the scope of this invention defined in the following claims.

1. A method comprising:
receiving a substrate comprising skeleton structures projecting out of a surface of the substrate;
using a chemical vapor deposition or liquid-phase deposition process to deposit deposited material on the skeleton structures, wherein the deposited material deposits between gaps between the skeleton structures; and
processing the deposited material.

2. The method of claim 1, wherein the deposited material comprises at least one of graphite, diamond, silicon carbide, tungsten carbide, titanium carbide, tantalum carbide, titanium, molybdenum, niobium, tantalum, tungsten, zirconium, hafnium, boron, or titanium boride.

3. The method of claim 1, wherein the skeleton structures are arranged with a porosity between 95% and 99.9%.

4. The method of claim 3, wherein a pore structure of the skeleton structures is nonuniform.

5. The method of claim 1, wherein a member of the skeleton structures comprises a diameter between 1 μm and 200 μm.

6. The method of claim 5, wherein a center-to-center separation between nearest neighboring substantially parallel members of the skeleton structures is between 10 μm and 1 mm.

7. The method of claim 1, wherein the skeleton structures are formed by laser mediated deposition.

8. The method of claim 1, wherein the skeleton structures comprise pyrolytic carbon.

9. The method of claim 1, wherein processing the deposited material comprises finishing the deposited material.

10. The method of claim 1, wherein processing the deposited material comprises densifying the deposited material.

11. The method of claim 1, further comprising alloying the skeleton and the deposited material.

12. A composite comprising:
a skeleton arranged at predetermined locations comprising skeleton material; and
deposited material deposited on and around the skeleton wherein the deposited material forms a unified material.

13. The composite of claim 12, wherein the skeleton material is different from the deposited material.

14. The composite of claim 12, wherein the skeleton is at most about 5% by volume of the composition of the composite.

15. The composite of claim 12, wherein the deposited material does not comprise an oxide.

16. The composite of claim 15, wherein the deposited material comprises at least one of graphite, diamond, silicon carbide, tungsten carbide, titanium carbide, tantalum carbide, titanium, molybdenum, niobium, tantalum, tungsten, zirconium, hafnium, boron, or titanium boride.

17. The composite of claim 12, wherein the skeleton comprises a plurality of free-standing members.

18. The composite of claim 17, further comprising a second deposited material wherein the second deposited material forms a layer grown on the skeleton material beneath the deposited material.

19. The composite of claim 12, wherein the skeleton comprises an interlocking structure.

20. The composite of claim 12, wherein the skeleton comprises carbon.

21. The composite of claim 12, wherein the skeleton is rigid.

22. The composite of claim 12, wherein the skeleton comprises a regular arrangement of skeleton members.

23. The composite of claim 22, wherein a void fraction of the skeleton is between 90 and 99.995%.
